(19) United States
(12) Patent Application Publication
(10) Pub. No.: US 2007/0176633 A1
(43) Pub. Date: Aug. 2, 2007

(54) Output circuit

(75) Inventor: Yukihito Kawabe, Kawasaki (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/405,524

(22) Filed: Apr. 18, 2006

(30) Foreign Application Priority Data
Jan. 31, 2006 (JP) 2006-023249

(51) Int. Cl. H03K 19/00

(52) U.S. Cl. 326/58

(57) ABSTRACT

An output circuit including: a tri-state output circuit capable of outputting high-impedance state, high-level state, and low-level state, in which the high-level state and low-level state are low-impedance state, and switching the high-impedance state and the low-impedance state in accordance with a first control signal; and a delay circuit outputting the first control signal to the tri-state output circuit by inputting a second control signal and delaying the second control signal so that timing delay time of the second control signal switching the high-impedance state to the low-impedance state is longer than the timing delay time of the second control signal switching the low-impedance state to the high-impedance state, is provided.

### CROSS-REFERENCE TO RELATED APPLICATIONS

This application is based upon and claims the benefit of priority from the prior Japanese Patent Application No. 2006-023249, filed on Jan. 31, 2006, the entire contents of which are incorporated herein by reference.

### BACKGROUND OF THE INVENTION

1. Field of the Invention

The present invention relates to an output circuit.

2. Description of the Related Art

Along with increasing power noise backed by current consumption increase in an LSI and lowering voltage in an internal circuit of the LSI, the need to reduce the power noise is increasing. Of these noises, for the noise arising from simultaneous switching of an I/O cell, a method with which noise arising from simultaneous switching of a plurality of I/O cells can be reduced is proposed (Patent document 1: Japanese Patent Application Laid-Open No. 2004-334271).

In addition to the noise arising from the simultaneous switching of the plurality of I/O cells, power noise sometimes arises in a single tri-state output circuit.

### SUMMARY OF THE INVENTION

An object of the present invention is to prevent malfunction caused by the power noise by reducing the power noise in the tri-state output circuit.

According to an aspect of the present invention, an output circuit including: a tri-state output circuit capable of outputting high-impedance state, high-level state, and low-level state, in which the high-level state and low-level state are low-impedance state, and switching the high-impedance state and the low-impedance state in accordance with a first control signal; and a delay circuit outputting the first control signal to the tri-state output circuit by inputting a second control signal and delaying the second control signal so that timing delay time of the second control signal switching the high-impedance state to the low-impedance state is longer than the timing delay time of the second control signal switching the low-impedance state to the high-impedance state, is provided.

### BRIEF DESCRIPTION OF THE DRAWINGS

FIG. 1 is a view showing an output circuit according to the present invention;

FIG. 2 is a circuit diagram showing a configuration example of a tri-state output circuit;

FIG. 3 is a timing chart showing a control signal of the circuit in FIG. 1;

FIG. 4 is a circuit diagram showing a configuration example of a delay circuit;

FIG. 5 is a circuit diagram showing another configuration example of the delay circuit;

FIG. 6 is a timing chart to explain an operation of the circuit in FIG. 5;

FIG. 7 is a circuit diagram showing another configuration example of the delay circuit;

FIG. 8 is a timing chart to explain an operation of the circuit in FIG. 7;

FIG. 9 is a timing chart to explain an operation of the delay circuit;

FIG. 10 is a circuit diagram showing another configuration example of the delay circuit;

FIG. 11 is a timing chart to explain an operation of the circuit in FIG. 10;

FIG. 12 is a circuit diagram showing another configuration example of the delay circuit;

FIG. 13 is a timing chart to explain an operation of the circuit in FIG. 12;

FIG. 14 is a view showing a level transition of a control signal according to a present embodiment and a range that an input signal can transit along therewith;

FIG. 15 is a view showing the tri-state output circuit;

FIG. 16 is a timing chart to explain an operation of the circuit in FIG. 15;

FIG. 17 is a timing chart showing a case where power noise arises in the tri-state output circuit; and

FIG. 18 is a view showing the level transition of the control signal and the range that the input signal can transit along therewith.

### DETAILED DESCRIPTION OF THE PREFERRED EMBODIMENTS

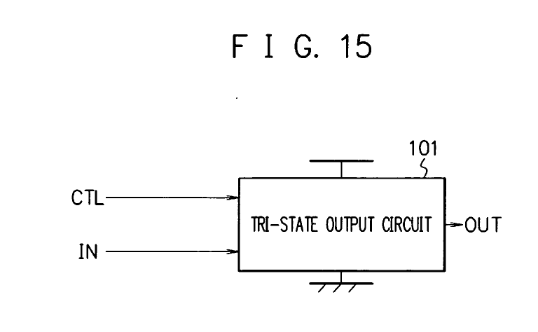

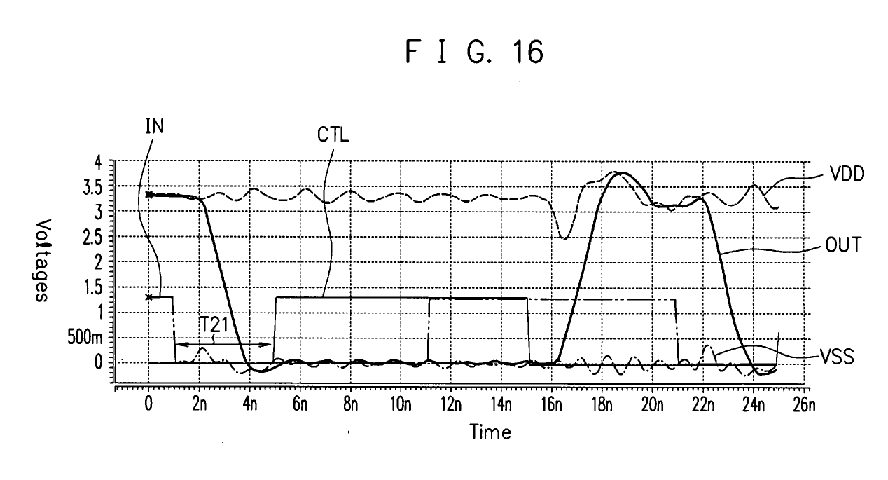

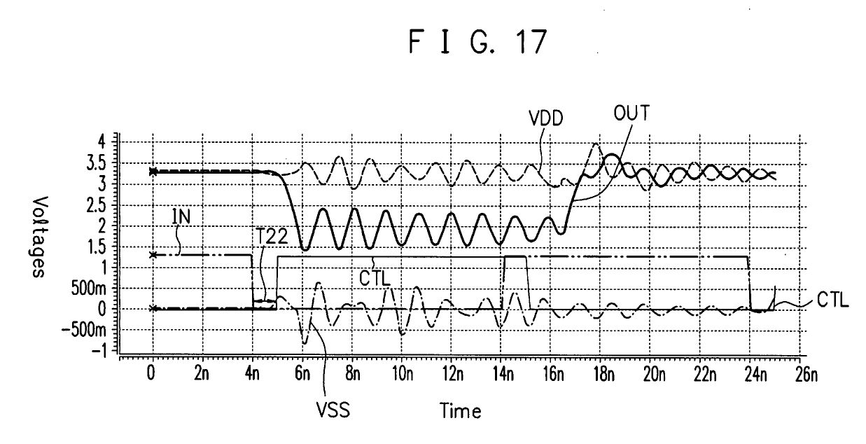

FIG. 15 is a view showing a tri-state output circuit 101 and FIG. 16 is a timing chart to explain its operation. Note that an input signal IN and a control signal CTL are shown in FIGS. 16 and 17 by slightly shifting their voltages for the purpose of distinguishing their level transitions. In actual, the input signal IN and the control signal CTL are at 0 (zero) V in their low level and at 1.3 V in their high level. A power supply voltage VDD is 3.3 V and a reference voltage VSS is 0 (zero) V.

The tri-state output circuit 101 is connected to between the power supply voltage VDD and the reference voltage VSS, and inputs the control signal CTL and the input signal IN and outputs an output signal OUT. When the control signal CTL is at low level and the input signal IN is at high level, the output signal OUT is also in a high-level state, and when the control signal CTL is at low level and the input signal IN is at low level, the output signal OUT is also in a low-level state. When the control signal CTL is at high level, the output of the tri-state output circuit 101 becomes the high-impedance state and the output signal OUT keeps the previous state. The tri-state output circuit 101 can output three states, namely the high-impedance state, the high-level state and the low-level state. In the high-level state and the low-level state, the output is in the low-impedance state.

A period T21 is a period from a rising edge of the input signal IN to a rising edge of the control signal CTL. The period T21 is enough long, causing almost no noise at the power supply voltage VDD and the reference voltage VSS. As a result, no noise arises at the output signal OUT.

FIG. 17 is a timing chart showing a case where the power noise arises at the tri-state output circuit 101, which corresponds to FIG. 16. A period T22 is the period from the rising edge of the input signal IN to the rising edge of the control signal CTL. Since the period 22 is too short, the noise arises at the power supply voltage VDD and the reference voltage VSS. As a result, the noise also arises at the output signal OUT. Specifically, with the change of the input signal IN from the high level to the low level, large current flows in the tri-state output circuit 101. In the course thereof, the control signal CTL changes from the low level to the high level, and thereby a transistor in the tri-state output circuit 101 performs switching operation. Therefore, the power noise arises.

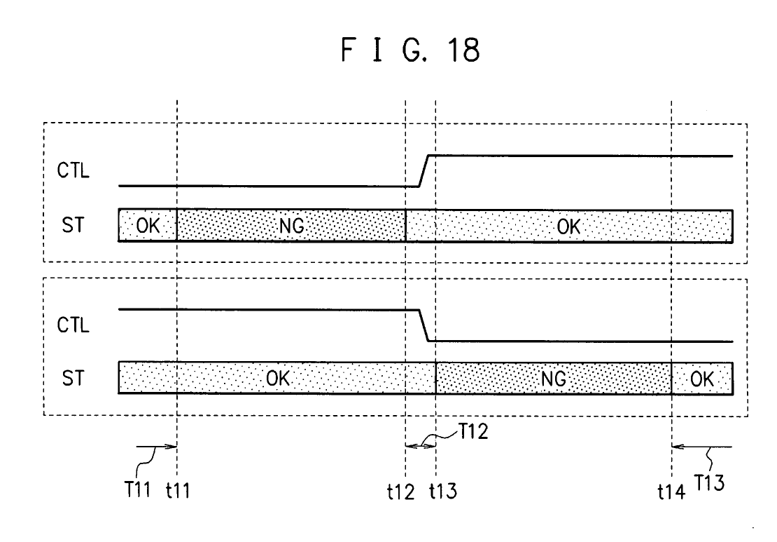

FIG. 18 is a view showing the level transition of the control signal CTL and a range ST that the input signal can transit along therewith. The upper side of the drawing shows a case where the control signal CTL changes from the low level (low-impedance state) to the high level (high-impedance state), and the lower side of the drawing shows a case where the. control signal CTL changes from the high level (high-impedance state) to the low level (low-impedance state).

First, the description will be given of the case where the control signal CTL changes from the low level to the high level at the upper side of the drawing. A case where the input signal IN performs level transition before a time t11 is the case shown in FIG. 16. When the input signal IN performs level transition, current flows in the tri-state output circuit 101 and the output signal OUT performs level transition. When the level transition of the output signal OUT is completed, the current flow in the tri-state output circuit 101 stops. Since the control signal CTL changes from the low level to the high level thereafter, the power noise does not arise.

A case where the input signal IN performs level transition between the time t11 and a time t12 is the case shown in FIG. 17. When the input signal IN performs level transition, large current flows in the tri-state output circuit 101. Since the control signal CTL changes from the low level to the high level during the large current flow, the power noise arises by the switching operation in the tri-state output circuit 101.

Subsequently, a case where the input signal IN performs level transition after the time t12 will be described. When the input signal IN performs level transition, current starts flowing in the tri-state output circuit 101. However, since the current flow is still small just after the start of the switching, almost no power noise arises even when the control signal CTL changes from the low level to the high level at this point.

Further, when the control signal CTL changes from the low level to the high level, the output of the tri-state output circuit 101 becomes the high-impedance state. Even when the input signal IN performs the level transition thereafter, the power noise does not arise.

Subsequently, the description will be given of the case where the control signal CTL changes from the high level to the low level at the lower side of the drawing.

A case where the input signal IN performs level transition before a time t13 will be described. When the control signal CTL is at the high level, the output of the tri-state output circuit 101 becomes the high-impedance state. Even when the input signal IN performs level transition in that state, the power noise does not arise.

In addition, when the control signal CTL changes from the high level to the low level, the transistor in the tri-state output circuit 101 performs switching operation, so that switching current starts flowing. However, since the current flow is still small just after the start of the switching, almost no power noise arises even when the input signal IN performs level transition at this point.

Subsequently, the description will be given of the case where the input signal IN performs level transition between the time t13 and a time t14. The above-described switching current flows by the change of the control signal CTL from the high level to the low level. The switching current becomes large current in time. When the input signal IN performs level transition during the large current flow, the power noise arises.

Subsequently, the description will be given of the case where the input signal IN performs level transition after the time t14. The above-described switching current flows by the change of the control signal CTL from the high level to the low level. When the level of the output signal OUT becomes stable, the switching current flow becomes very small. Even when the input signal IN performs the level transition thereafter, the power noise does not arise.

The period between the time t11 and t12 is several ns. A period T12 between the time t12 and t13 is several tens ps to a hundred and several tens ps. The period between the time t13 and t14 is several ns. Periods T11, T12, T13 are overlapped periods at the upper and lower sides of the drawing in which no noise arises.

The case where the control signal CTL transits from the low level to the high level as stated above is shown at the upper side of the drawing. When the input signal IN changes when the control signal CTL is at the low level (low-impedance state), the output signal OUT of the tri-state output circuit 101 performs switching. When the control signal CTL transits from the low level to the high level in the course of this switching, the current flowing between the power sources is abruptly cut by the transistor driving the output, so that the noise larger than that of normal switching is caused at the power source.

Further, the case where the control signal CTL transits from the high level to the low level is shown at the lower side of the drawing. With the control signal CTL changing from the high level to the low level, when the input signal IN reverses in the course of the switching of the tri-state output circuit 101, abrupt current change is caused between the power source and the tri-state output circuit 101 as in the case of the upper side in the drawing, so that the noise larger than that of the normal switching is caused at the power source.

Thus, when simultaneous switchings are performed by the input signal IN and the control signal CTL, the noise larger than that of the normal switching is caused at the power source, so that a circuit design in consideration only of the normal switching possibly leads to malfunction of an internal circuit. This problem can be avoided when a logic design allowing the input signal IN not to change at the switching clock cycle of the control signal CTL can be realized, however, this solution is not always applicable when the timing requirement of the control signal CTL is demanding.

When trying to avoid this problem by adjusting delay between the input signal IN and the control signal CTL, the switching timing by the input signal IN and the control signal CTL needs to satisfy the following requirements.

First, the requirement for the control signal CTL at the upper side in the drawing to transit from the low level to the high level will be described. The control signal CTL changes before the switching current of the tri-state output circuit 101 has increased to a certain level, or after the switching current has become small enough, backed by the change in the input signal IN.

Subsequently, the requirement for the control signal CTL to transit from the high level to the low level will be described. The input signal IN changes before the switching current of the tri-state output circuit 101 has increased to a certain level, or after the switching current has become small enough, backed by the change in the control signal CTL.

As will be understood by FIG. 18, the requirements for the transition of the input signal IN and the control signal CTL are opposite to each other in terms of order at the rising and falling of the control signal CTL, so that the transition timings of the control signal CTL and the input signal IN need to have enough intervals or be extremely close to each other. As will be described below, there are three measures.

First, an enough interval is set between the transition timing of the control signal CTL and that of the input signal IN. However, in this case, there arises a problem of degrading delay performance to a large extent.

Secondly, as a measure against the noise, the power source is enhanced. However, in this case, there arises a problem of increasing cost in that the size of a semiconductor chip increases.

Thirdly, the transition timings of the control signal CTL and the input signal IN are set to extremely close to each other. However, in this case, there arises a problem of increasing man-hours for design in that the many tri-state output circuits (input/output circuits) 101 require adjustment. Further, depending on characteristics of the tri-state output circuit 101, there may be a case where almost no interspace for the adjustment exists between timings, in which the measure is not executable.

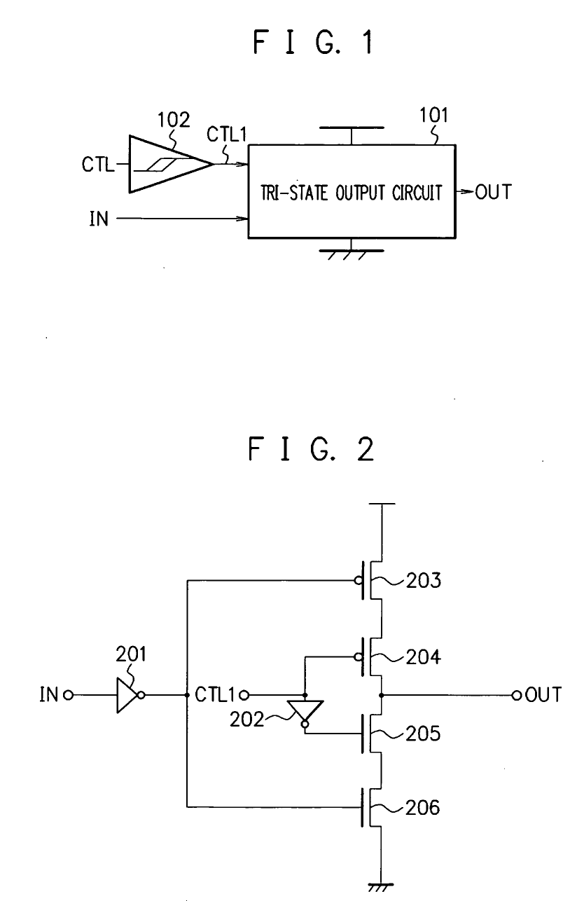

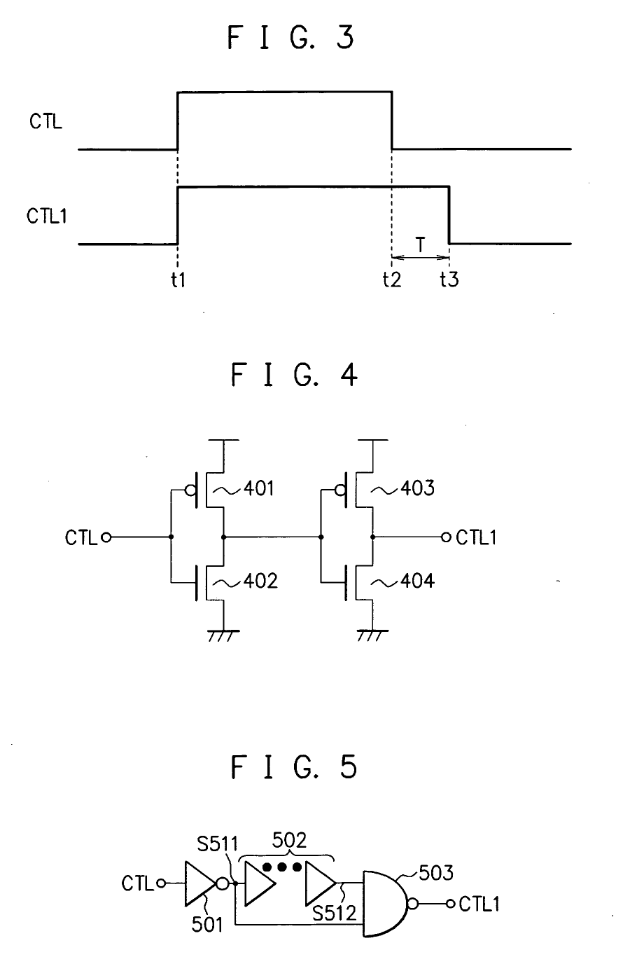

FIG. 1 is a view showing an output circuit according to an embodiment of the present invention, and FIG. 3 is a timing chart showing the control signal CTL and a control signal CTL1. The output circuit is a semiconductor integrated circuit having the tri-state output circuit 101 and a delay circuit 102.

At a time t1, the control signals CTL, CTL1 transit from the low level to the high level. At a time t2, the control signal CTL transits from the high level to the low level. At a time t3, the control signal CTL1 transits from the high level to the low level. The period between the time t2 and t3 is a delay time T. When the control signal CTL has risen, the delay circuit 102 outputs the control signal CTL1 substantially without delay; and when the control signal CTL has fallen, the delay circuit 102 outputs the control signal CTL1 after a predetermined delay time T.

Specifically, the delay circuit 102 outputs the control signal CTLl to the tri-state output circuit 101 by delaying the control signal CTL so that the timing delay time of the control signal CTL when switching from the high level to the low level becomes longer than the timing delay time (for example, 0 (zero)) of the control signal CTL when switching from the low level to the high level. The delay circuit 102 can generate the control signal CTL1 having hysteresis characteristic with respect to the control signal CTL.

As in FIG. 16, the tri-state output circuit 101 is connected to between the power supply voltage VDD and the reference voltage VSS, and inputs the control signal CTL1 and the input signal IN and outputs the output signal OUT. When the control signal CTL1 is at the low level and the input signal IN is at the high level, the output signal OUT also becomes the high-level state, and when the control signal CTL1 is at the low level and the input signal IN is at the low level, the output signal OUT also becomes the low-level state. When the control signal CTL1 is at the high level, the output of the tri-state output circuit 101 becomes the high-impedance state and the output signal OUT keeps the previous state. The tri-state output circuit 101 can output three states, namely the high-impedance state, the high-level state and the low level state. In the high-level state and the low-level state, the output states are in the low-impedance state, respectively. The output of the tri-state output circuit 101 becomes the high-impedance state when the control signal CTL1 is at the high level, and the output becomes the low-impedance state when the control signal CTL1 is at the low level.

FIG. 2 is a circuit diagram showing a configuration example of the tri-state output circuit 101. An inverter (NOT) circuit 201 logically inverts the input signal IN to output it. An inverter circuit 202 logically inverts the control signal CTL1 to output it. Hereinafter, a MOS field effect transistor is simply referred to as a transistor. A p-channel transistor 203 is connected to an output terminal of the inverter circuit 201 via a gate thereof, the power voltage VDD via a source thereof, and a source of a p-channel transistor 204 vie a drain thereof. The p-channel transistor 204 is connected to a line of the control signal CTL1 via a gate thereof and a line of the output signal OUT via a drain thereof. An n-channel transistor 205 is connected to an output terminal of the inverter circuit 202 via a gate thereof, a line of the output signal OUT via a drain thereof, and a drain of an n-channel transistor 206 vie a source thereof. The n-channel transistor 206 is connected to an output terminal of the inverter circuit 201 via a gate thereof and the reference voltage VSS via a source thereof.

When the control signal CTL1 becomes the high level, the transistors 204, 205 turn OFF. Based on this, the line of the output signal OUT becomes the high-impedance state. When the control signal CTL1 becomes the low level, the transistors 204, 205 turn ON. Based on this, the line of the output signal OUT becomes the low-impedance state.

When the control signal CTL1 is at the low-level and the input signal IN becomes the high level, the transistors 203 to 205 turn ON, and the transistor 206 turns OFF. Based on this, the output signal OUT becomes the high level (power voltage VDD).

When the control signal CTL1 is at the low level and the input signal IN becomes the low level, the transistors 204 to 206 turn ON, and the transistor 203 turns OFF. Based on this, the output signal OUT becomes the low level (reference voltage VSS).

FIG. 4 is a circuit diagram showing a configuration example of the delay circuit 102. A p-channel transistor 401 is connected to a line of the control signal CTL via a gate thereof, the power voltage VDD via a source thereof, and a drain of an n-channel transistor 402 via a drain thereof. The n-channel transistor 402 is connected to a line of the control signal CTL via a gate thereof and the reference voltage VSS via a source thereof. A p-channel transistor 403 is connected to a mutual contact point of the drains of the transistors 401, 402 via a gate thereof, the power voltage VDD via a source thereof, and a line of the control signal CTL1 via a drain thereof. A p-channel transistor 404 is connected to the mutual contact point of the drains of the transistors 401, 402 via a gate thereof, the line of the control signal CTL1 via a drain thereof, and the reference voltage VSS via a source thereof.

The transistor 403 has larger driving force than that of the transistor 404. Specifically, the transistor 403 is larger than the transistor 404 in size (gate width). The transistor 403 allows larger current flow and thereby allows the control signal CTL1 to become the high level at high speed. On the other hand, the transistor allows smaller current flow and thereby allows the control signal CTL1 to become the low level at low speed. As a result, as shown in FIG. 3, the control signal CTL1 has a shorter delay time when rising and a longer delay time when falling as compared to the control signal CTL.

Further, the same result can be obtained when making the transistor 402 have a larger driving force as compared to the transistor 401. In other words, the result can be obtained by enhancing the driving force(s) of the transistor 402 and/or the transistor 403 for making the control signal CLT1 be at the high level, and by reducing the driving force(s) of the transistor 401 and/or the transistor 404 for making the control signal CLT1 be at the low level. Note that an example in which the delay circuit 102 is configured by double-tiered inverters has been described, however, the number of tier(s) is not limited thereto. In the double-tiered case, a first-tier inverter is composed of the transistors 401, 402, and the second-tier inverter is composed of the transistors 403, 404.

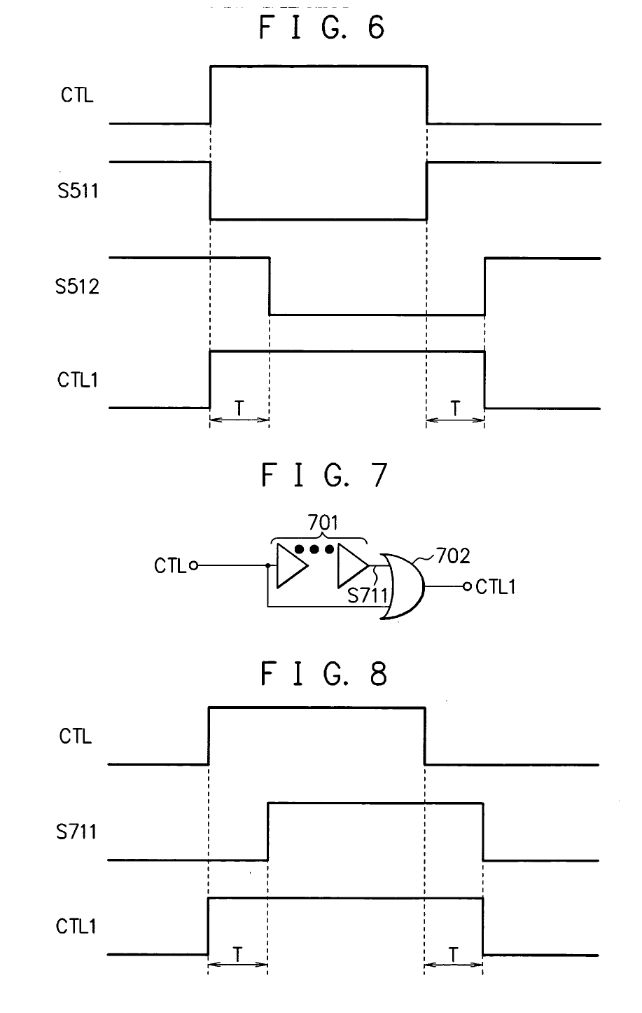

FIG. 5 is a circuit diagram showing another configuration example of the delay circuit 102 and FIG. 6 is a timing chart to explain its operation. The delay circuit 102 includes a logic circuit and a delay element. An inverter circuit 501 logically inverts the control signal CTL to output a signal S551. A delay element (buffer) 502 delays the output signal S551 from the inverter circuit 501 by the delay time T to output a signal S512. A nonconjunction (NAND) circuit 503 outputs the nonconjunction of the signals S511 and S512 as the control signal CTL1.

FIG. 7 is a circuit diagram showing another configuration example of the delay circuit 102 and FIG. 8 is a timing chart to explain its operation. The delay circuit 102 includes a logic circuit and a delay element. A delay element 701 delays the control signal CTL by the delay time T to output a signal S711. A logical sum (OR) circuit 702 outputs the logical sum of the signal S711 and the control signal CTL as the control signal CTL1.

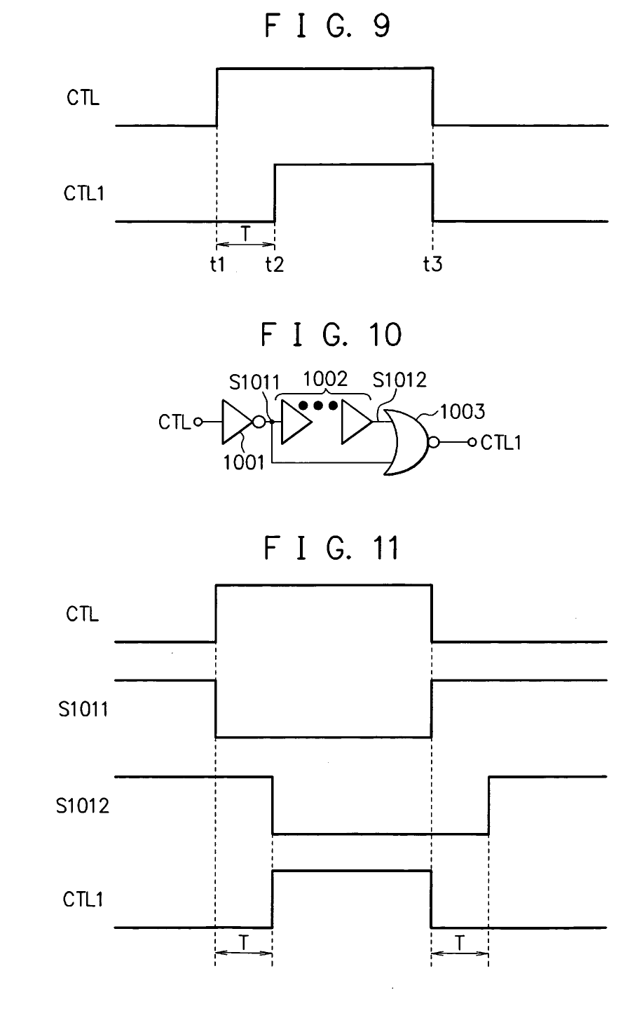

In the above, the case where the output of the tri-state output circuit 101 becomes the high-impedance state when the control signal CTL1 is at the high level, and it becomes the low-impedance state when the control signal CTL1 is at the low level has been descried. Conversely, it is also possible that the output of the tri-state output circuit 101 becomes the low-impedance state when the control signal CTL1 is at the high level and that it becomes the high-impedance state when the control signal CTL1 is at the low level. The operation of the delay circuit 102 in that case is shown in FIG. 9.

FIG. 9 is a timing chart to explain the operation of the delay circuit 102. At a time t1, the control signal CTL transits from the low level to the high level. At a time t2, the control signal CTL1 transits from the low level to the high level. At a time t3, the control signals CTL, CTL1 transit from the high level to the low level. The period between the time t1 and t2 is the delay time T. When the control signal CTL has risen, the delay circuit 102 outputs the control signal CTL1 with a delay of the predetermined delay time T; and when the control signal CTL has fallen, the delay circuit 102 outputs the control signal CTL1 substantially without delay.

In this case, the delay circuit 102 can also be configured by the circuits in FIG. 4. Contrary to the above, the result can also be obtained by reducing the driving force(s) of the transistor 402 and/or the transistor 403 for making the control signal CLT1 be at the high level, and by enhancing the driving force(s) of the transistor 401 and/or the transistor 404 for making the control signal CLT1 be at the low level.

FIG. 10 is a circuit diagram showing a configuration example of the delay circuit 102 generating the control signal CLT1 in FIG. 9, and FIG. 11 is a timing chart to explain its operation. The delay circuit 102 includes a logic circuit and a delay element. An inverter circuit 1001 logically inverts the control signal CTL to output a signal S1011. A delay element 1002 delays the output signal S1011 of the inverter circuit 1001 by the delay time T to output a signal S1012. A negative logical sum (NOR) circuit 1003 outputs the negative logical sum of the signals S1011 and S1012 as the control signal CTL1.

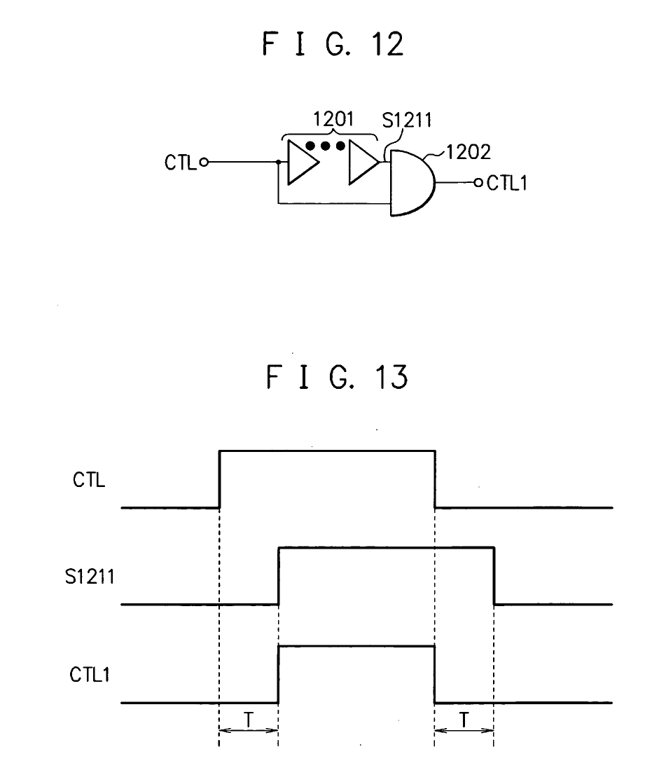

FIG. 12 is a circuit diagram showing a configuration example of the delay circuit 102 generating the control signal CLT1 in FIG. 9, and FIG. 13 is a timing chart to explain its operation. The delay circuit 102 includes a logic circuit and a delay element. A delay element 1201 delays the control signal CTL by the delay time T to output a signal S1211. A conjunction (AND) circuit 1202 outputs the conjunction of the signal S1211 and the control signal CTL as the control signal CTL1.

As described above, the delay circuit 102 inputs the control signal CTL and outputs the control signal CTL1 to the tri-state output circuit 101 by delaying the control signal CTL so that the timing delay time of the control signal CTL switching the tri-state output circuit 101 from the high-impedance state to the low-impedance state becomes longer than the timing delay time (for example, 0 (zero)) of the control signal CTL switching the tri-state output circuit 101 from the low-impedance state to the high-impedance state.

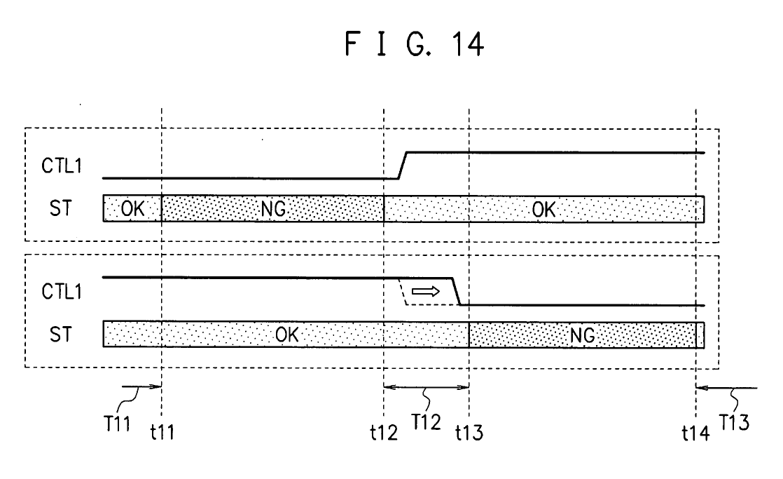

FIG. 14 is a view showing the level transition of the control signal CTL1 according to the present embodiment and a range ST that the input signal can transit along therewith, which corresponds to FIG. 18. The upper side of the drawing shows a case where the control signal CTL1 changes from the low level (low-impedance state) to the high level (high-impedance state), and the lower side of the drawing shows a case where the control signal CTL1 changes from the high level (high-impedance state) to the low level (low-impedance state).

As shown at the upper side of the drawing, when the control signal CTL changes from the low level (low-impedance state) to the high level (high-impedance state), the control signal CTL1 is generated with almost no delay.

Contrary thereto, as shown at the lower side of the drawing, when the control signal CTL changes from the high level (high-impedance state) to the low level (low-impedance state), the control signal CTL1 is generated after the predetermined delay time T. Based on this, the period T12 between the time t12 and the time t13 in FIG. 14 can be made longer as compared to the case in FIG. 18. The period T12 is low noise, allowing the input signal IN to perform level transition. By increasing the period T12, for those unable to eliminate power noise sufficiently due to small interspace for delay adjustment, it becomes possible to eliminate the noise; and also for those originally having the interspace, it becomes easy to adjust the delay as a measurement against noise with the increased interspace.

As an example, in the timing chart of FIG. 18, it is assumed that when the level transition time of the control signal CTl is 0 (zero), the times t11, t12, t13, t14 are −3 ns, −30 ps, +30 ps, +3 ns respectively. Specifically, assuming the tri-state output circuit 101 in which the signal-change timings of the control signal CTL and input signal IN are required to be within ±30 ps or ±3 ns or more for preventing the power noise.

With this circuit, when adjusting delay between the input signal IN and control signal CTL for preventing power noise, the interspace T12 for delay adjustment for the input signal IN is only 60 ps. When the region T12 is not adopted, T11 or T13 respectively having an interspace of 3 ns or more has to be adopted. Considering the case where there are a number of tri-state output circuits (I/O cells) 101 requiring adjustment as in an interactive I/O bus of large bits or of the variation in delay, smaller interspace T12 for delay adjustment makes the delay adjustment be extremely difficult. This state forces a power noise increase or a delay adjustment at 3 ns level, leading to malfunction or delay worsening.

Subsequently, assuming the case where the delay circuit 102 is inserted as in FIG. 1 in accordance with the present embodiment. The delay circuit 102 generates the control signal CTL1 on the assumption that the delay time when the control signal CTL transits from the high-impedance state to the low-impedance state is 270 ps, and the delay time when the control signal CTL transits from the low-impedance state to the high-impedance state is 30 ps.

In this case, in FIG. 14, the time t11, t12, t13, t14 are −2.97 ns, 0 (zero), 300 ps, +3.27 ns, respectively. The period T12 between the time t12 and t13 is 300 ps. The range T12 allowing delay adjustment when the control signal CTL1 and the input signal IN perform simultaneous switching increases from 60 ps to 300 ps as compared to the case in FIG. 18. Based on this, when the input signal IN is adjusted to come close to the center of the interspace T12 by performing delay adjustment of the input signal IN, power noise prevention becomes easy even if large-bit adjustment and variation in delay are taken into account.

According to the present embodiment, it is possible to improve delay performance by preventing delay-performance degradation caused by delay degradation due to the power noise of the tri-state output circuit 101 and significant delay adjustment to prevent the power noise (by setting large interval between the transition timings of the input signal IN and the control signal CTL). Further, the power noise caused by simultaneous switching by the input signal IN and the control signal CTL of the tri-state output circuit 101 can be reduced.

By generating the control signal CTL1 being delayed control signal CTL, it is possible to delay the switching timing from the high-impedance state to the low-impedance state. With this, the time range allowing transition between the high-level state and the low-level state can be increased, so that the noise can be prevented. Also, the malfunction caused by the noise can be prevented. The present embodiment can apply to a semiconductor integrated circuit to reduce the power noise of an I/O circuit.

By generating the first control signal being delayed second control signal, the switching timing from the high-impedance state to the low-impedance state can be delayed. With this, the time range allowing transition between the high-level state and the low-level state can be increased, so that the noise can be prevented. Further, malfunction caused by the noise can be prevented.

The present embodiments are to be considered in all respects as illustrative and no restrictive, and all changes which come within the meaning and range of equivalency of the claims are therefore intended to be embraced therein. The invention may be embodied in other specific forms without departing from the spirit or essential characteristics thereof.

What is claimed is:

1. An output circuit comprising:
a tri-state output circuit capable of outputting high-impedance state, high-level state, and low-level state, in which the high-level state and low-level state are low-impedance state, and switching the high-impedance state and the low-impedance state in accordance with a first control signal; and
a delay circuit outputting the first control signal to said tri-state output circuit by inputting a second signal and delaying the second control signal so that timing delay time of the second control signal switching the high-impedance state to the low-impedance state is longer than the timing delay time of the second control signal switching from the low-impedance state to the high-impedance state.

2. The output circuit according to claim 1,
wherein said tri-state output circuit inputs an input signal and outputs the high-level state or the low-level state in accordance with the input signal when the low-impedance state is instructed by the first control signal.

3. The output circuit according to claim 1,
wherein said delay circuit includes a first transistor generating the first control signal to place said tri-state output circuit into the high-impedance state, and a second transistor generating the first control signal to place said tri-state output circuit into the low-impedance state, and
wherein the first transistor has larger driving force than that of the second transistor.

4. The output circuit according to claim 3,
wherein the first transistor is larger than the second transistor in size.

5. The output circuit according to claim 1,
wherein said delay circuit has a logic circuit and a delay element.

6. The output circuit according to claim 1,
wherein said tri-state output circuit outputs the high-impedance state when the first control signal is at the high level, and outputs the low-impedance state when the first control signal is at the low level.

7. The output circuit according to claim 6,
wherein said delay circuit includes a first transistor to place the first control signal into the high level and a second transistor to place the first control signal into the low level, and
wherein the first transistor has larger driving force than that of the second transistor.

8. The output circuit according to claim 7,
wherein the first transistor is larger than the second transistor in size.

9. The output circuit according to claim 6,
wherein said delay circuit has a logic circuit and a delay element.

10. The output circuit according to claim 9,
wherein said delay circuit includes an inverter circuit to logically invert the second control signal, a delay element to delay the output signal of the inverter circuit, and a nonconjunction circuit to output a nonconjunction of the output signals of the inverter circuit and the delay element.

11. The output circuit according to claim 9,
wherein said delay circuit includes a delay element to delay the second control signal and a logical sum circuit to output a logical sum of the output signal of the delay element and the second control signal.

12. The output circuit according to claim 1,
wherein said tri-state output circuit outputs the high-impedance state when the first control signal is at the low level, and outputs the low-impedance state when the first control signal is at the low level.

13. The output circuit according to claim 12,
wherein said delay circuit includes a first transistor to place the first control signal into the high level and a second transistor to place the first control signal into the low level, and
wherein the second transistor has larger driving force than that of the first transistor.

14. The output circuit according to claim 13,
wherein the second transistor is larger than the first transistor in size.

15. The output circuit according to claim 12,
wherein said delay circuit has a logic circuit and a delay element.

16. The output circuit according to claim 15,
wherein said delay circuit includes an inverter circuit to logically invert the second signal, a delay element to delay the output signal of the inverter circuit, and a negative logical sum circuit to output a negative logical sum of the output signals of the inverter circuit and the delay element.

17. The output circuit according to claim 15,
wherein said delay circuit includes a delay element to delay the second control signal and a conjunction circuit to output a conjunction of the output signals of the delay element and the second control signal.
